(19) United States
(12) Patent Application Publication
(10) Pub. No.: US 2026/0018222 A1
(43) Pub. Date: Jan. 15, 2026

(54) ONE-TIME PROGRAMMABLE MEMORY CELL

(71) Applicant: EMEMORY TECHNOLOGY INC., HSINCHU (TW)

(72) Inventors: LUN-CHUN CHEN, HSINCHU COUNTY (TW); PING-LUNG HO, HSINCHU COUNTY (TW); TSAO-HSIN YANG, HSINCHU COUNTY (TW)

(21) Appl. No.: 19/256,195

(22) Filed: Jul. 1, 2025

Related U.S. Application Data
(60) Provisional application No. 63/671,307, filed on Jul. 15, 2024.

(51) Int. Cl. G11C 17/16; G11C 17/18; H10B 20/25

(52) U.S. Cl. CPC G11C 17/16; G11C 17/18; H10B 20/25

(57) ABSTRACT

A one-time programmable (OTP) memory cell includes an anti-fuse element and a selection circuit. The anti-fuse element includes a first terminal, a second terminal coupled to a program line, and a gate terminal. The selection circuit is coupled to the first terminal of the anti-fuse element, a word line, and a bit line. The selection circuit controls an electrical connection between the bit line and the first terminal of the anti-fuse element according to a voltage of the word line. The OTP memory cell is programmed by a program operation, and a channel between the first terminal and the second terminal of the anti-fuse element is damaged by the program operation.

### CROSS REFERENCE

This application claims the benefit of prior-filed U.S. provisional application No. 63/671,307, filed on Jul. 15, 2024, which is incorporated by reference in its entirety.

### TECHNICAL FIELD

The present disclosure relates to a one-time programmable memory device, and more particularly, to one-time programmable memory device with low program voltage.

### DISCUSSION OF THE BACKGROUND

As semiconductor manufacturing processes continue to advance, the size of transistors has been significantly reduced overtime. The reduction in size not only reduces the circuit areas but also enables the use of lower operating voltages, thereby improving power efficiency. However, the continued miniaturization of transistors has also introduced new challenges, particularly in the form of reduced voltage tolerance.

For example, when advanced nodes are adopted for fabricating one-time programmable (OTP) memory cells, the programming process can face some challenges. Traditional programming operations often require applying high voltages to the transistor gates on the channels. However, in advanced nodes, these voltages may exceed the junction breakdown voltage of the transistors, causing programming inefficiencies or failures. Consequently, the development of OTP memory cells that utilize advanced nodes and operate effectively at lower voltages has become a critical issue in the field.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides an OTP memory cell. The OTP memory cell includes an anti-fuse element, and a selection circuit. The anti-fuse element includes a first terminal, a second terminal coupled to a program line, and a gate terminal. The selection circuit is coupled to the first terminal of the anti-fuse element, a word line, and a bit line. The selection circuit controls an electrical connection between the bit line and the first terminal of the anti-fuse element according to a voltage of the word line. When the OTP memory is programmed by a program operation, a channel between the first terminal and the second terminal of the anti-fuse element is damaged.

Another aspect of the present disclosure provides an OTP array. The OTP array includes a first OTP memory cell and a second OTP memory cell. The first OTP memory cell includes a first anti-fuse element, and a first selection circuit. The first anti-fuse element includes a first terminal, a second terminal coupled to a first program line, and a gate terminal. The first selection circuit is coupled to the first terminal of the first anti-fuse element, a first word line, and a first bit line. The first selection circuit controls an electrical connection between the first bit line and the first terminal of the first anti-fuse element according to a voltage of the first word line. The second OTP memory cell includes a second anti-fuse element and a second selection circuit. The second anti-fuse element includes a first terminal, a second terminal coupled to the first program line, and a gate terminal. The second selection circuit is coupled to the first terminal of the second anti-fuse element, the first word line, and a second bit line. The second selection circuit controls an electrical connection between the second bit line and the first terminal of the second anti-fuse element according to a voltage of the first word line. When the first OTP memory cell is programmed by a program operation, a channel between the first terminal and the second terminal of the first anti-fuse element is damaged by the program operation.

Another aspect of the present disclosure provides a physical unclonable function (PUF) cell. The PUF cell includes a first OTP memory cell and a second OTP memory cell. The first OTP memory cell includes a first anti-fuse element and a first selection circuit. The first anti-fuse element includes a first terminal, a second terminal coupled to a program line, and a gate terminal. The first selection circuit is coupled to the first terminal of the first anti-fuse element, a first word line, and a first bit line. The first selection circuit controls an electrical connection between the first bit line and the first terminal of the first anti-fuse element according to a voltage of the first word line. The second OTP memory cell includes a second anti-fuse element and a second selection circuit. The second anti-fuse element includes a first terminal, a second terminal coupled to the program line, and a gate terminal. The second selection circuit is coupled to the first terminal of the second anti-fuse element, a second word line, and a second bit line. The second selection circuit controls an electrical connection between the second bit line and the first terminal of the second anti-fuse element according to a voltage of the second word line. When the PUF cell is enrolled by an enrollment operation, one of the first OTP memory cell and the second OTP memory cell is programmed by causing damage to its channel while the other one of the first OTP memory cell and the second OTP memory cell is not programmed.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a one-time programmable (OTP) memory cell according to one embodiment of the present disclosure.

FIG. 2 shows the voltages provided to the OTP memory cell in FIG. 1 during the program operation according to one embodiment of the present disclosure.

FIG. 3 shows the voltages provided to the OTP memory cell in FIG. 1 during the read operation according to one embodiment of the present disclosure.

FIG. 4 shows a relation between the program time and the read current of the OTP memory cell in FIG. 1 according to one embodiment of the present disclosure.

FIG. 5 shows a relation between the gate voltage applied to the gate terminal of the anti-fuse element and the read current of the OTP memory cell in FIG. 1 during the read operation according to one embodiment of the present disclosure.

FIG. 6 shows a three-dimensional architecture diagram of the OTP memory cell in FIG. 1 according to one embodiment of the present disclosure.

FIG. 7 shows a cross-sectional view of the anti-fuse element of the OTP memory cell.

FIG. 8 shows an OTP memory cell according to another embodiment of the present disclosure.

FIG. 9 shows an OTP array according to one embodiment of the present disclosure.

FIG. 10 shows a PUF cell according to one embodiment of the present disclosure.

### DETAILED DESCRIPTION

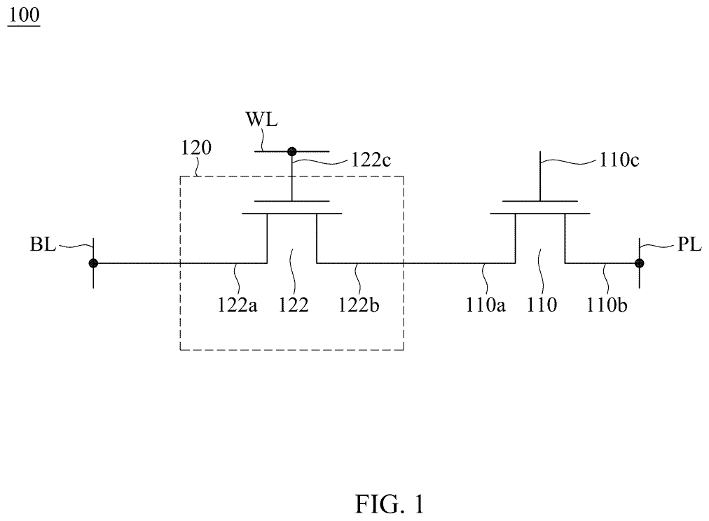

FIG. 1 shows a one-time programmable (OTP) memory cell 100 according to one embodiment of the present disclosure. The OTP memory cell 100 includes an anti-fuse element 110 and a selection circuit 120. The anti-fuse element 110 includes a first terminal 110a, a second terminal 110b coupled to a program line PL, and a gate terminal 110c. The selection circuit 120 is coupled to the first terminal 110a of the anti-fuse element 110, a word line WL, and a bit line BL. The selection circuit 120 may control an electrical connection between the bit line BL and the first terminal 110a of the anti-fuse element 110 according to a voltage of the word line WL.

In the embodiment shown in FIG. 1, the selection circuit 120 may include a select transistor 122, which includes a first terminal 122a coupled to the bit line BL, a second terminal 122b coupled to the first terminal 110a of the anti-fuse element 110, and a gate terminal 122c coupled to the word line WL.

Initially, the OTP memory cell 100 can have a first state (i.e., an initial state), which may be, for example but not limited to, corresponding to a bit value “0”, and after a program operation of the OTP memory cell 100, the OTP memory cell 100 can be programmed to have a second state, which may be, for example but not limited to, corresponding to bit value “1”. In some embodiments, the program operation may cause damage to the channel between the first terminal 110a and the second terminal 110b of the anti-fuse element 110, which results in a short channel effect and the resistance change of the channel. Therefore the damaged channel can induce a high subthreshold leakage current from the second terminal 110b to the first terminal 110a during a read operation of the OTP memory cell 100 with the second terminal 110b being configured as the drain for receiving a high voltage. Since the leakage current will not be induced if the OTP memory cell 100 has not been programmed, the bit value stored in the OTP memory cell 100 can be read by sensing the reading current during the read operation.

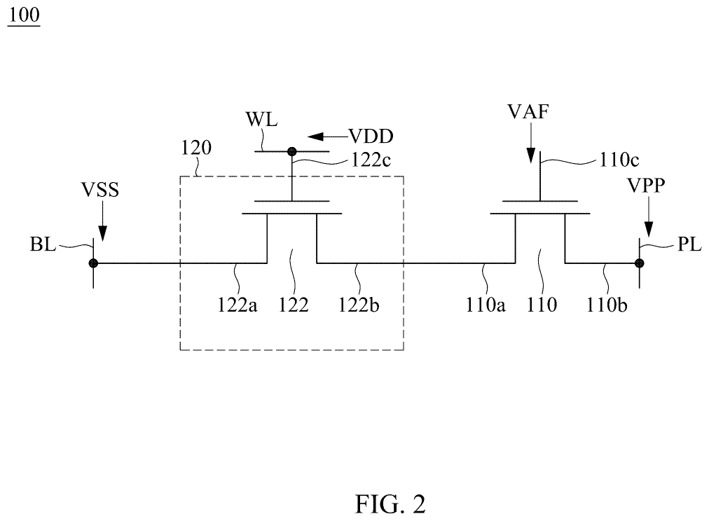

FIG. 2 shows the voltages provided to the OTP memory cell 100 during the program operation according to one embodiment of the present disclosure. During the program operation, the bit line BL may receive a voltage VSS, the word line WL may receive a voltage VDD, the program line PL may receive a voltage VPP, and the gate terminal of the anti-fuse element 110 may receive a voltage VAF or be floating. The voltage VPP can be greater than the voltage VDD, and the voltage VDD can be greater than voltage VSS and the voltage VAF. In some embodiments, the voltage VSS can be the ground voltage, such as 0V, and the voltage VDD can be the power voltage of the OTP memory cell 100 and can be in the range from 0.3V to 1.2V. In some embodiments, the voltage VPP can be in the range from 2V to 6V, and the voltage VAF can be in the range from −0.5V to 0.5V, such as 0V.

In such case, during the program operation, the select transistor 122 can be turned on, so the first terminal 110a of the anti-fuse element 110 can receive the voltage VSS through the select transistor 122 and the bit line BL. As a result, when the high voltage VPP is applied to the second terminal 110b of the anti-fuse element 110, it may cause high-density defects in the channel between the first terminal 110a and the second terminal 110b or damage the gate oxide at the gate terminal 110c. In some embodiments, both the density defects in the channel and the gate oxide damage can induce leakage currents during the read operation, thereby differentiating the OTP memory cell 100 that has been programed from those are not programmed.

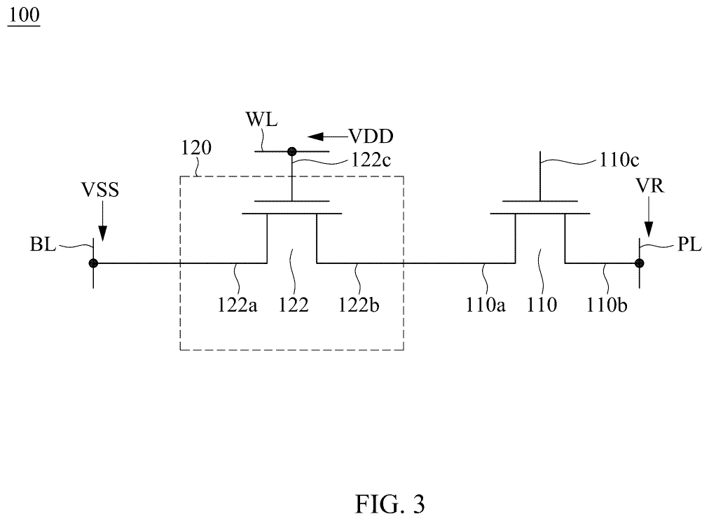

FIG. 3 shows the voltages provided to the OTP memory cell 100 during the read operation according to one embodiment of the present disclosure. During the read operation, the bit line BL receives the first voltage VSS, the word line WL receives the voltage VDD, the program line PL receives a voltage VR, and the gate terminal 110c of the anti-fuse element 110 may be floating. The voltage VR is greater than or equal to the voltage VDD, and may be in the range from 0.3V to 2V. For example, the voltage VDD can be 0.4V and the voltage VR can be 0.8V.

During the read operation, the select transistor 122 can be turned on, so the first terminal 110a of the anti-fuse element 110 can receive the voltage VSS through the select transistor 122 and the bit line BL. In such case, if the channel between the first terminal 110a and the second terminal 110b of the anti-fuse element 110 has been damaged during the program operation, then the voltage VR applied to the second terminal 110b of the anti-fuse element 110 would induce a subthreshold leakage current (or tunneling current) flowing from the second terminal 110b to the first terminal 110a of the anti-fuse element 110, and thus, a significant current can be sensed from the bit line BL.

In addition, in some embodiments, if the gate oxide at the gate terminal 110c of the anti-fuse element 110 has been damaged during the program operation, then the gate terminal 110c may be charged to a higher voltage, thereby turning on the anti-fuse element 110 and contributing a significant current to the bit line BL.

In other words, during the program operation, two different programming mechanisms that can help to produce the read currents in the read operation may occur: one is the channel damage and the other is the gate oxide damage. In the present embodiment, the gate terminal 110c of the anti-fuse element 110 can be floating during the read operation, so that the read currents caused by the two programming mechanisms can both be induced to contribute the final read current. However, the present disclosure is not limited thereto. In some cases, to ensure the gate terminal 110c to be floating and not affected by other signals may require special attention in circuit design, which may not always be desirable. Therefore, the gate terminal 110c of the anti-fuse element 110 may receive the voltage VAF during the read operation in some embodiments. In such case, since the gate terminal 110c is coupled to the voltage VAF near 0V, the programming mechanism of gate oxide damage may not contribute to the final read current. However, the programming mechanism of the damaged channel can still cause significant read current during the read operation and allow the identification of the bit value of the OTP memory cell 100.

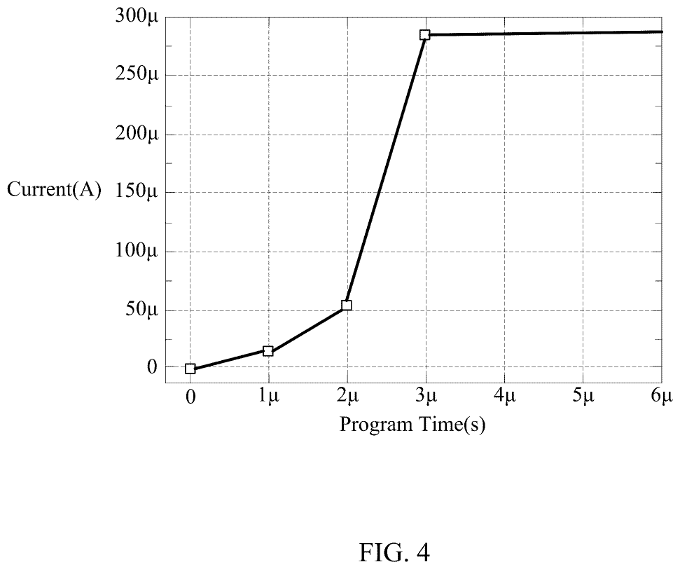

FIG. 4 shows a relation between the program time and the read current of the OTP memory cell 100 according to one embodiment of the present disclosure. As shown in FIG. 4, if the OTP memory cell 100 has not been programmed, no read current or only insignificant read current is observed. However, when the programming time of the program operation reaches 2 μs, a read current of 50 μA can be observed.

Furthermore, it can be noticed that when the programming time of the program operation reaches 3 μs, the read current will further increase to a saturate value around 280 μA, and the significant increase in the read current is mainly contributed by the subthreshold leakage current due to the defects in the channel of the anti-fuse element 110 caused during the program operation. In some embodiments, to leverage the high read current for facilitating the identification of the bit value stored in the OTP memory cell 100, the program operation may be extended to more than 3 μs or long enough to cause the channel damage of the anti-fuse element 110. However, the present disclosure is not limited thereto. In some embodiments, the read current caused by the gate oxide damage is also significant enough for bit value identification, and thus the time for program operation may be reduced to, for example, 1 or 2 μs.

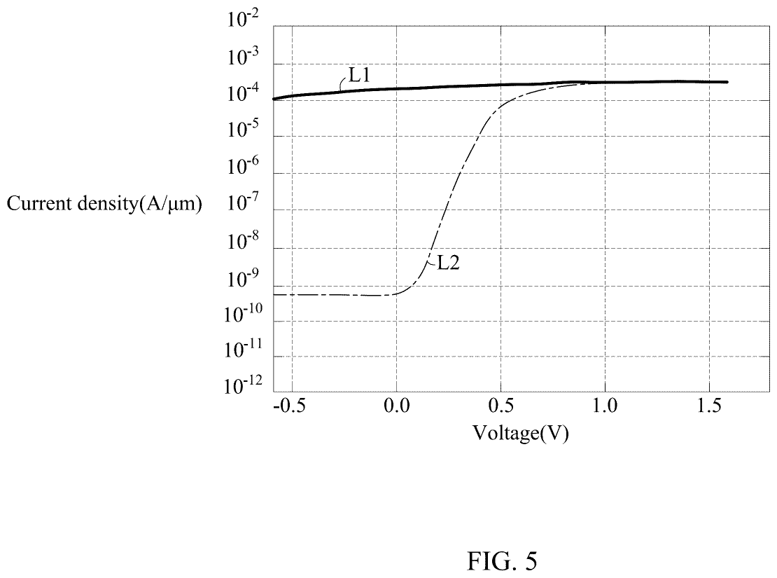

FIG. 5 shows a relation between the gate voltage applied to the gate terminal 110c of the anti-fuse element 110 and the current density of the OTP memory cell 100 during the read operation according to one embodiment of the present disclosure. In FIG. 5, the solid line L1 illustrates the case that the OTP memory cell 100 has been programmed for more than 3 μs and the dotted and dashed line L2 illustrates the case that the OTP memory cell 100 has not been programmed yet.

As shown in FIG. 5, if the OTP memory cell 100 has not been programmed, then the read current will not become significant before the gate voltage reaches the threshold voltage of the anti-fuse element 110 (e.g., 0.3V). However, if the OTP memory cell 100 has been programmed previously, then the current density can reach 10⁻⁴ A/μm even when the gate voltage is 0V. Therefore, in some embodiments, the gate voltage applied to the gate terminal 110c of the anti-fuse element 110 can be set to 0V for the read operation since the difference between the read current generated by the programmed OTP memory cell and the read current generated by the unprogrammed OTP memory cell is significant enough to be sensed.

In the present embodiment, the channel damage is the main programming mechanism to cause the read current in the read operation, and the voltage applied to the anti-fuse element 110 for damaging the channel of the anti-fuse element 110 in the program operation can be relatively low (e.g., 2V to 6V); therefore, the program operation can be performed effectively for the anti-fuse element 110 having a small size and a lower junction breakdown voltage.

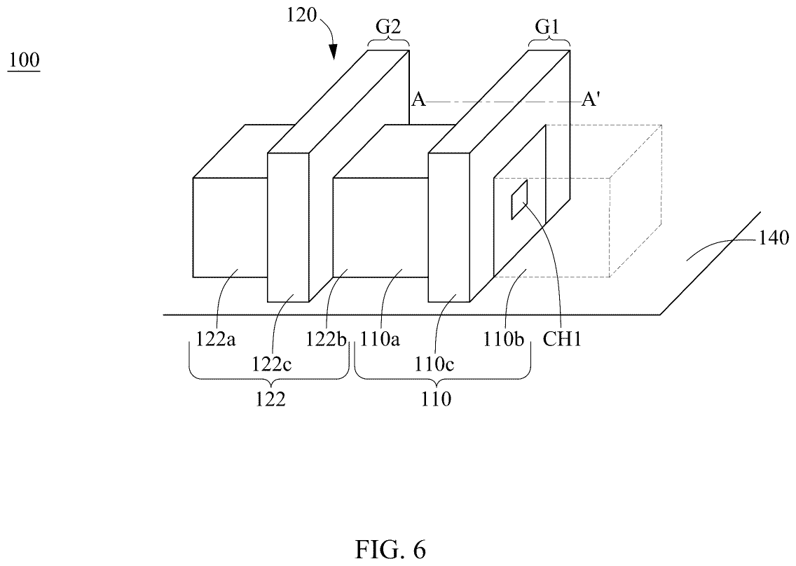

In such case, the anti-fuse element 110 can be transistors manufactured by an advanced process node. FIG. 6 shows a three-dimensional architecture diagram of the OTP memory cell 100 according to one embodiment of the present disclosure. In the embodiment shown in FIG. 6, the anti-fuse element 110 and the transistor 122 are both implemented by gate-all-around (GAA) field effect transistors (FETs).

As shown in FIG. 6, the first terminal 110a can be a source of the anti-fuse element 110 and the second terminal 110b can be a drain of the anti-fuse element 110. The source and drain of the anti-fuse element 110 are disposed at two ends of the gate structure G1 at the gate terminal 110c with a channel CH1 surrounding by the gate structure G1 and connecting between the source and the drain of the anti-fuse element 110.

Also, the first terminal 122a of the select transistor 122 can be a source of the select transistor 122, and the second terminal 122b can be a drain of the select transistor 122. The source and drain of the select transistor 122 are disposed at two ends of the gate structure G2 at the gate terminal 122c with a channel (not shown) surrounding by the gate structure G2 and connecting between the source and the drain of the select transistor 122. In the present embodiment, the source of the anti-fuse element 110 and the drain of the select transistor 122 can be formed in a combined region; however, the present disclosure is not limited thereto. In some embodiments, the source of the anti-fuse element 110 and the drain of the select transistor 122 can be separated.

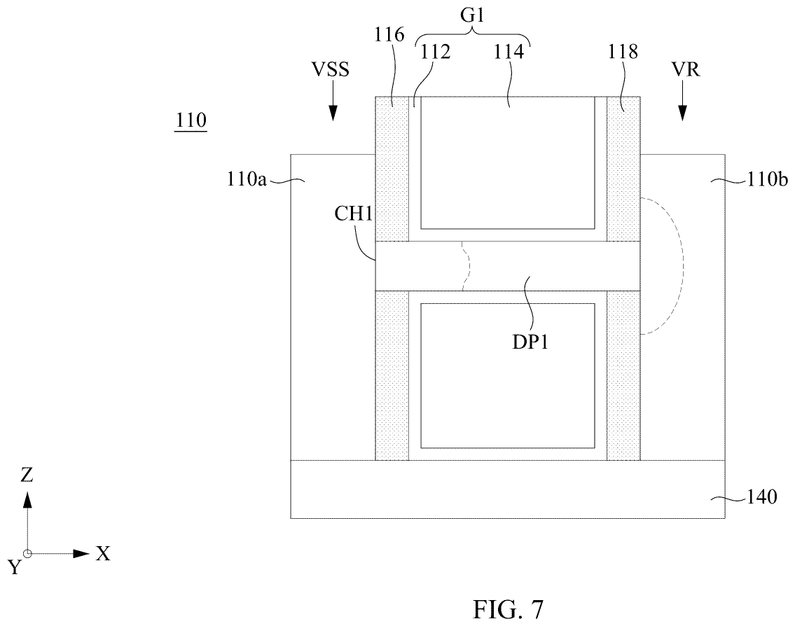

FIG. 7 shows a cross-sectional view of the anti-fuse element 110 by cutting along the line AA′ in FIG. 6. In the present embodiment, the anti-fuse element 110 can be an N-Channel metal-oxide silicon (NMOS) transistor. In such case, the first terminal 110a (i.e., the source) and the second terminal 110b (i.e., the drain) can be doped with N-type carriers, and the channel CH1 is lightly doped with P-type carriers. The source and the drain are disposed on the substrate 140.

The gate structure G1 includes dielectric layers 112 and gate layers 114 surrounded by the dielectric layers 112. The dielectric layers 112 may include silicon oxide, silicon nitride or high-K dielectric material. The gate layer 114 may include polysilicon or a metal gate electrode. The gate structure G1 is disposed between the first terminal 110a (i.e., the source) and the second terminal 110b (i.e., the drain), the spacer 116 is disposed between the gate structure G1 and the first terminal 110a, and the spacer 118 is disposed between the gate structure G1 and the second terminal 110b.

Furthermore, in FIG. 7, the OTP memory cell 100 is under the read operation, and thus, the second terminal 110b receives the voltage VR and the first terminal 110a receives the voltage VSS. In such case, the depletion region DP1 within the channel CH1 can extend from the second terminal 110b to an area close to the first terminal 110a. Such situation is caused because the channel length of the anti-fuse element 110 is rather short, for example, shorter than 20 nm, and the program operation may cause damage to the channel CH1 during the program operation. As a result, during the read operation, a high subthreshold leakage current (or tunneling current) can be induced.

Although the anti-fuse element 110 and the select transistor 122 are implemented by GAAFETs in the embodiment shown in FIG. 6, the present disclosure is not limited thereto. In some embodiments, the anti-fuse element be a metal oxide semiconductor field effect transistor (MOSFET) or a diode. Also, in some embodiments, the anti-fuse element 110 can be implemented by other advanced processes. For example, the anti-fuse element 110 can be a FinFET, a Junctionless FET, or a Nanosheet FET. Furthermore, in some embodiments, while the anti-fuse element may be fabricated using advanced nodes, the selection circuit 120 including the select transistor 122 may be produced using mature nodes.

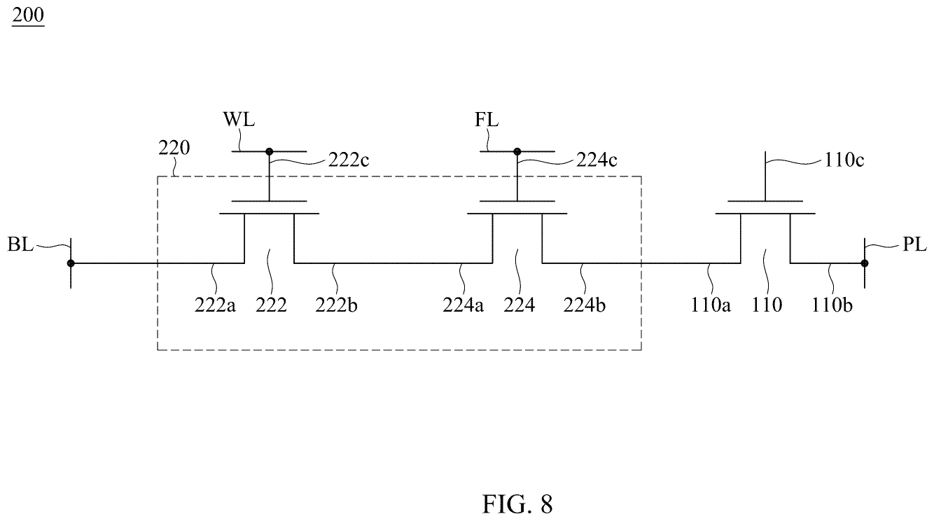

FIG. 8 shows an OTP memory cell 200 according to another embodiment of the present disclosure. The OTP memory cell 200 is different from the OTP memory cell 100 in that the selection circuit 220 of the OTP memory cell 200 includes the select transistor 222 and the following transistor 224. Specifically, the select transistor 222 include a first terminal 222a coupled to the bit line BL, a second terminal 222b, and a control terminal 222c coupled to the word line WL. The following transistor 224 includes a first terminal 224a coupled to the second terminal 222b of the select transistor 222, a second terminal 224b coupled to the first terminal 110a of the anti-fuse element 110, and a gate terminal 224c coupled to a following line FL.

In the present embodiment, the following transistor 224 can reduce the cross voltage applied to the select transistor 222 so as to reduce the gate-induced-drain-leakage (GIDL) and prevent the punch current. In some embodiments, the OTP memory cell 200 may receive the same voltages shown in FIG. 2 for performing the program operation with the following line FL receiving a voltage VDD2 that is between the voltage VDD and the voltage VPP. Also, the OTP memory cell 200 may receive the same voltages shown in FIG. 3 for performing the read operation with the following line FL receiving the voltage VDD.

In some embodiments, to further reduce the GIDL, the channel of the following transistor 224 can be lighter doped. On the other hand, the doping concentration of the channel of the anti-fuse element 110 can be higher so that the channel can be susceptible to damage during the program operation. In some embodiments, the doping concentration of the channel of the anti-fuse element 110 can be higher than the doping concentration of the channel of the following transistor 224 and the doping concentration of the channel of the select transistor 222. However, the present disclosure is not limited thereto.

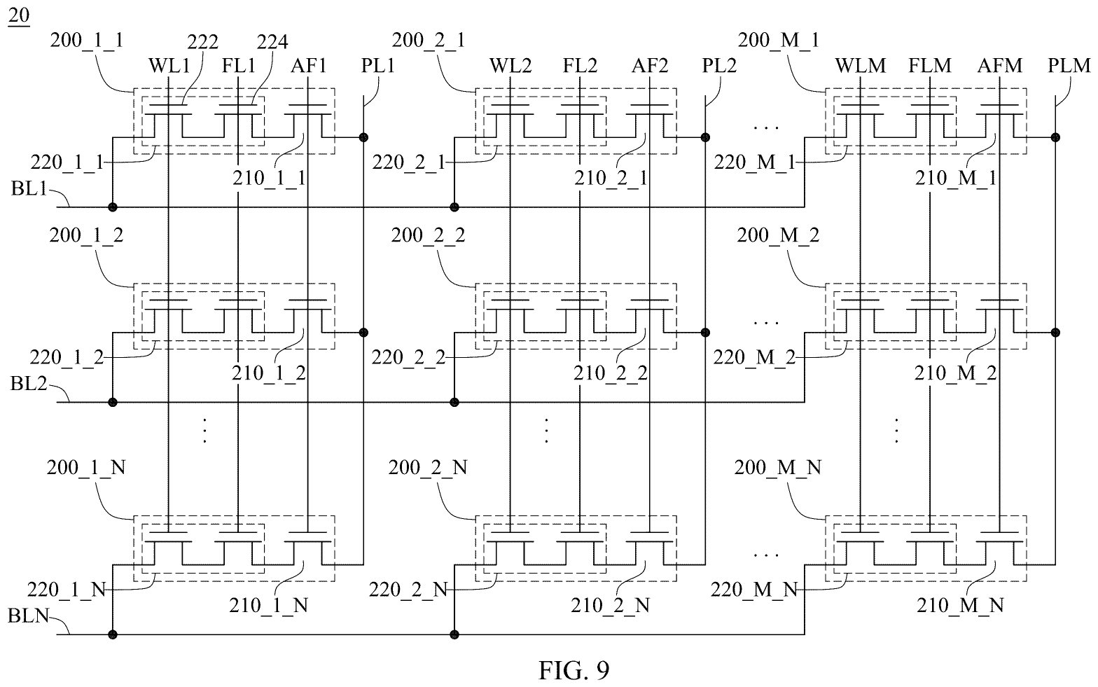

FIG. 9 shows an OTP array 20 according to one embodiment of the present disclosure. The OTP array 20 includes a plurality of OTP memory cell 200_1_1 to OTP memory cell 200_M_N that are arranged in an M×N array, wherein M and N are integers greater than 1. In the present embodiment, each of the OTP memory cells 200_1_1 to 200_M_N may have a same structure as the OTP memory cell 200 shown in FIG. 8.

As shown in FIG. 9, OTP memory cells arranged in a same row may be coupled to a same bit line, and OTP memory cells arranged in a same column may be coupled to a same word line, a same following line, a same anti-fuse line, and a same program line.

For example, OTP memory cells 200_1_1, 200_1_2, and 200_1_N are arranged in the same column. In such case, the anti-fuse element 210_1_1 in the OTP memory cell 200_1_1 includes a first terminal, a second terminal coupled to a program line PL1, and a gate terminal coupled to an anti-fuse line AF1. Also, the selection circuit 220_1_1 including a select transistor 222 and a following transistor 224 is coupled to the first terminal of the anti-fuse element 210_1_1, a word line WL1, a following line FL1, and a bit line BL1. The selection circuit 220_1_1 controls the electrical connection between the bit line BL1 and the first terminal of the anti-fuse element 210_1_1 according to a voltage of the word line WL1.

Also, the anti-fuse element 210_1_2 in the OTP memory cell 200_1_2 includes a first terminal, a second terminal coupled to the program line PL1, and a gate terminal coupled to the anti-fuse line AF1. Also, the selection circuit 220_1_2 is coupled to the first terminal of the anti-fuse element 210_1_2, the word line WL1, the following line FL1, and a bit line BL2. The selection circuit 220_1_2 controls the electrical connection between the bit line BL2 and the first terminal of the anti-fuse element 210_1_2 according to a voltage of the word line WL1. Similarly, the anti-fuse element 210_1_N is coupled to the bit line BLN, the word line WL1, the following line FL1, the anti-fuse line AF1, and the program line PL1.

Furthermore, OTP memory cells 200_1_1, 200_2_1, and 200_M_1 are arranged in the same row. In such case, the anti-fuse element 210_2_1 in the OTP memory cell 200_2_1 includes a first terminal, a second terminal coupled to a program line PL2, and a gate terminal coupled to an anti-fuse line AF2. Also, the selection circuit 220_2_1 is coupled to the first terminal of the anti-fuse element 210_2_1, a word line WL2, a following line FL2, and the bit line BL1. The selection circuit 220_2_1 controls the electrical connection between the bit line BL1 and the first terminal of the anti-fuse element 210_2_1 according to a voltage of the word line WL2. Similarly, the anti-fuse element 210_M_1 is coupled to the bit line BL1, a word line WLM, a following line FLM, an anti-fuse line AFM and a program line PLM.

With the arrangement of the OTP array 200, each of the OTP memory cells 200_1_1 to 200_M_N can be programmed and read independently. For example, when the program operation is performed upon the OTP memory cell 200_1_1, the voltage VSS can be applied to the bit line BL1, the voltage VDD can be applied to the word line WL1, the voltage VDD2 can be applied to the following line FL1, and the program voltage VPP can be applied to the program line PL1. Also, the voltage VAF can be applied to the anti-fuse line AFL1. In such case, the select transistor 222 and the following transistor 224 in the selection circuit 220_1_1 can be turned on, and a high voltage would be applied between the first terminal and the second terminal of the anti-fuse element 210_1_1, thereby causing high-density defects in the channel so as to program the OTP memory cell 200_1_1.

In addition, during the program operation of the OTP memory cell 200_1_1, the voltage VDD can be applied to the bit lines BL2 to BLN, and thus, the voltages applied to the anti-fuse elements 200_1_2 to 200_1_N can be reduced, thereby preventing the OTP memory cells 200_1_2 to 200_1_N from being programmed. Furthermore, during the program operation of the OTP memory cell 200_1_1, the voltage VSS can be applied to the word lines WL2 to WLM and the program lines PL2 to PLM. As a result, no high voltage is applied to the anti-fuse elements 200_2_1 to 200_2_M, and thus, the OTP memory cells 200_2_1 to 200_2_M will not be programmed during the program operation of the OTP memory cells 200_1_1.

In the present embodiment, the following lines FL1 to FLM can all be coupled to each other, however, the present disclosure is not limited thereto. In some embodiments, the following lines FL1 to FLM may also be controlled separately. Furthermore, in the present embodiment, gate terminals of the anti-fuse elements 210_1_1 to 210_M_N can be coupled to the anti-fuse lines AF1 to AFM correspondingly for receiving the voltage VAF. However, in some other embodiments, the gate terminals of the anti-fuse elements 210_1_1 to 210_M_N can be physically floating without connecting to each other.

Furthermore, in some embodiments, each of the OTP memory cells 200_1_1 to 200_M_N may be replaced by the OTP memory cell 100 by omitting the following transistors 224 and the following lines FL1 to FLM.

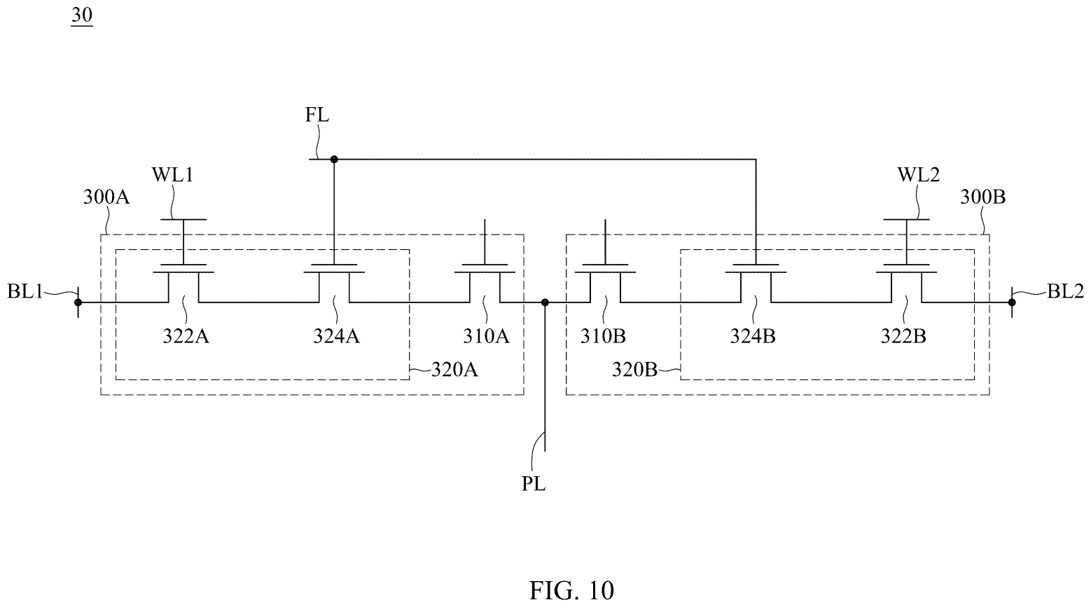

In addition, in some embodiments, the OTP memory cells 100 and 200 may also be adopted to form a physical unclonable function (PUF) cell. FIG. 10 shows a PUF cell 30 according to one embodiment of the present disclosure. The PUF cell 30 includes two OTP memory cell 300A and 300B.

For example, the OTP memory cell 300A includes the anti-fuse element 310A and a selection circuit 320A. The anti-fuse element 310A includes a first terminal, a second terminal coupled to a program line PL, and a gate terminal. The selection circuit 320A is coupled to the first terminal of the anti-fuse element 310A, a word line WL1, and a bit line BL1, and the selection circuit 320A controls the electrical connection between the bit line BL1 and the first terminal of the anti-fuse element 310A according to the voltage of the word line WL1. The anti-fuse element 310B includes a first terminal, a second terminal coupled to the program line PL, and a gate terminal. The selection circuit 320B is coupled to the first terminal of the anti-fuse element 310B, a word line WL2, and a bit line BL2, and the selection circuit 320B controls the electrical connection between the bit line BL2 and the first terminal of the anti-fuse element 310B according to the voltage of the word line WL2.

In the present embodiment, the selection circuits 320A and 320B may have the same structure as the selection circuit 220. That is, the selection circuits 320A may include a select transistor 322A and a following transistor 324A, and the selection circuits 320B may include a select transistor 322B and a following transistor 324B. In some embodiments, the gate terminal of the following transistor 324A and the gate terminal of the following transistor 324B can be coupled to the same following line FL.

The PUF cell 30 can be enrolled by an enrollment operation, and one of the OTP memory cells 300A and 300B will be programmed by causing damage to its channel while the other one of the OTP memory cells 300A and 300B will not be programmed. Specifically, during the enrollment operation, the bit lines BL1 and BL2 may both receive the VSS, the word lines WL1 and WL2 may both receive the voltage VDD, the program line PL may receive the voltage VPP, and the following line FL may receive the voltage VDD2. Also, the gate terminal of the anti-fuse element 310A and the gate terminal of the anti-fuse element 310B may both receive the voltage VAF or be floating.

In such case, both the OTP memory cell 300A and 300B may be programmed, however, due to the different intrinsic characteristics caused by manufacturing variations of the OTP memory cell 300A and 300B, one of the OTP memory cells 300A and 300B will be programmed first. Furthermore, the OTP memory cell that is programmed first will conduct a current from the program line PL to the corresponding bit line BL1 or BL2, thereby reducing the stress applied to the other OTP memory cell and preventing the other OTP memory cell from being programmed. Therefore, after enrollment, the OTP memory cells 300A and 300B will have different bit values, and an unpredictable bit value can be derived by reading the OTP memory cell 300A through the bit line BL1 or the OTP memory cell 300B through the bit line BL2. Alternatively, in some embodiments, the unpredictable bit value can be read by sensing both the bit line BL1 and the bit line BL2 as a differential pair.

Since the PUF cell 30 allows one of the OTP memory cell 300A or 300B to be programmed with a relative low program voltage VPP by damaging the channel of the anti-fuse element therein, the PUF cell 30 can be implemented by transistors using advanced node processes that have smaller sizes and operate under lower voltages.

In summary, the OTP memory cells, the OTP array, and the PUF cells provided by the embodiments of the present disclosure allows the OTP memory cell to be programmed with a relative low program voltage by damaging the channel of the anti-fuse element therein, the OTP memory cells, the OTP array, and the PUF cells can be implemented by transistors using advanced node processes that have smaller sizes and operate under lower voltages.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A one-time programmable (OTP) memory cell comprising:
an anti-fuse element comprising a first terminal, a second terminal coupled to a program line, and a gate terminal; and
a selection circuit coupled to the first terminal of the anti-fuse element, a word line, and a bit line, and configured to control an electrical connection between the bit line and the first terminal of the anti-fuse element according to a voltage of the word line;
wherein when the OTP memory cell is programmed by a program operation, a channel between the first terminal and the second terminal of the anti-fuse element is damaged.

2. The OTP memory cell of claim 1, wherein the anti-fuse element is a metal oxide semiconductor field effect transistor (MOSFET), a gate-all-around (GAA) field effect transistor (FET), a FinFET, a Junctionless FET, a Nanosheet FET, or a diode.

3. The OTP memory cell of claim 1, wherein a channel length of the anti-fuse element is less than 20 nm.

4. The OTP memory cell of claim 1, wherein the selection circuit comprises a select transistor comprises a first terminal coupled to the bit line, a second terminal coupled to the first terminal of the anti-fuse element, and a gate terminal coupled to the word line.

5. The OTP memory cell of claim 4, wherein:
during the program operation, the bit line is configured to receive a first voltage, the word line is configured to receive a second voltage, the program line is configured to receive a third voltage, and the gate terminal of the anti-fuse element is configured to receive a fourth voltage or to be floating, and
the third voltage is greater than the second voltage, the second voltage is greater than first voltage and the fourth voltage.

6. The OTP memory cell of claim 5, wherein:
during a read operation, the bit line is configured to receive the first voltage, the word line is configured to receive the second voltage, the program line is configured to receive a fifth voltage, and the gate terminal of the anti-fuse element is configured to receive the fourth voltage or to be floating, and
the fifth voltage is greater than or equal to the second voltage.

7. The OTP memory cell of claim 1, wherein the selection circuit comprises:
a select transistor comprising a first terminal coupled to the bit line, a second terminal, and a gate terminal coupled to the word line; and
a following transistor comprising a first terminal coupled to the second terminal of the select transistor, a second terminal coupled to the first terminal of the anti-fuse element, and a gate terminal coupled to a following line.

8. The OTP memory cell of claim 7, wherein:
during the program operation, the bit line is configured to receive a first voltage, the word line is configured to receive a second voltage, the program line is configured to receive a third voltage, the gate terminal of the anti-fuse element is configured to receive a fourth voltage or to be floating, and the following line is configured to receive a sixth voltage, and
the third voltage is greater than the second voltage and the sixth voltage, the sixth voltage is greater than the second voltage, and the second voltage is greater than the first voltage and the fourth voltage.

9. The OTP memory cell of claim 8, wherein:
during a read operation, the bit line is configured to receive the first voltage, the word line and the following line are configured to receive the second voltage, the program line is configured to receive a fifth voltage, and the gate terminal of the anti-fuse element is configured to receive the fourth voltage or to be floating, and
the fifth voltage is greater than or equal to the second voltage.

10. The OTP memory cell of claim 7, wherein a doping concentration of the channel of the anti-fuse element is higher than a doping concentration of a channel of the following transistor.

11. The OTP memory cell of claim 1, wherein the program operation is kept beyond a predetermined time to ensure the channel between the first terminal and the second terminal of the anti-fuse element is damaged.

12. The OTP memory cell of claim 1, wherein during a read operation, a high subthreshold leakage current from the second terminal of the anti-fuse element to the first terminal of the anti-fuse element is induced.

13. A one-time programmable (OTP) array comprising:
a first OTP memory cell comprising:
a first anti-fuse element comprising a first terminal, a second terminal coupled to a first program line, and a gate terminal; and
a first selection circuit coupled to the first terminal of the first anti-fuse element, a first word line, and a first bit line, and configured to control an electrical connection between the first bit line and the first terminal of the first anti-fuse element according to a voltage of the first word line; and
a second OTP memory cell comprising:
a second anti-fuse element comprising a first terminal, a second terminal coupled to the first program line, and a gate terminal; and
a second selection circuit coupled to the first terminal of the second anti-fuse element, the first word line, and a second bit line, and configured to control an electrical connection between the second bit line and the first terminal of the second anti-fuse element according to a voltage of the first word line;
wherein when the first OTP memory cell is programmed by a program operation, a channel between the first terminal and the second terminal of the first anti-fuse element is damaged.

14. The OTP array of claim 13, further comprising:
a third OTP memory cell comprising:
a third anti-fuse element comprising a first terminal, a second terminal coupled to a second program line, and a gate terminal; and
a third selection circuit coupled to the first terminal of the third anti-fuse element, a second word line, and the first bit line, and configured to control an electrical connection between the first bit line and the first terminal of the third anti-fuse element according to a voltage of the second word line.

15. The OTP array of claim 14, wherein the gate terminal of the first anti-fuse element, the gate terminal of the second anti-fuse element, and the gate terminal of the third anti-fuse element are floating.
